(19) United States
(12) Patent Application Publication
(10) Pub. No.: US 2026/0219701 A1
(43) Pub. Date: Jul. 30, 2026

(54) LOW-LATENCY WORD ALIGNMENT FOR SERDES INTERFACES USING INLINE PATTERNS

(71) Applicant: QUALCOMM Incorporated, San Diego, CA (US)

(72) Inventors: Chad Everett WINEMILLER, Cary, NC (US); Masoud ROHAM, San Diego, CA (US); Seuk SON, San Diego, CA (US); Masoud FARSHBAF ZINATI, San Diego, CA (US); Thimmaiah BOLKARANDA SUBBAIAH, San Diego, CA (US)

(21) Appl. No.: 19/040,704

(22) Filed: Jan. 29, 2025

(51) Int. Cl. G06F 1/04

(52) U.S. Cl. CPC G06F 1/04

(57) ABSTRACT

A communication interface circuit that enables low-latency word alignment in a serial interface includes a deserializer, a clock generation circuit and a synchronization circuit. The deserializer is configured to convert a serial datastream received from a data communication link to multibit data words and to output the multibit data words in accordance with timing provided by a parallel clock signal. The clock generation circuit is configured to generate the parallel clock signal by dividing a bit clock signal that is coupled to a clock input of the deserializer. The synchronization circuit is configured to suppress the parallel clock signal when the data communication link is idle for a first period of time and reestablish output of the parallel clock signal after a second period of time that follows detection of a pulse on the data communication link. The clock generation circuit may be reset when the pulse is detected.

### TECHNICAL FIELD

The present disclosure relates generally to interfaces that include serial and deserializer circuits and, more particularly, to synchronization of clock signals used for deserialization.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever and improvements in process technology have been adopted to implement underlying processing and communication circuits.

Increased bandwidth demands attributable to feature and service expansion often necessitate the use of an expanded number of data communication links, which requires increased numbers of input/output (I/O) terminals. In many implementations, I/O terminals are not available to communicate control signals that would be otherwise be usable for synchronization between transmitters and receivers. In certain circumstances, loss of synchronization can substantially limit maximum data throughput rates, may prevent a data communication link from adhering to latency specifications and may render the data communication link unusable for applications associated with time-critical constraints. There is an ongoing need to improve the design of communication interfaces to respond to increased demands for functionality, performance and reliability.

### SUMMARY

Certain aspects of the disclosure relate to an integrated circuit (IC) device that includes, or is coupled to a serial data link. In various aspects of the disclosure, the IC device includes a communication interface circuit that has a deserializer, a clock generation circuit and a synchronization circuit. The deserializer may be configured to convert a serial datastream received from a data communication link to multibit data words and to output the multibit data words in accordance with timing provided by a parallel clock signal. The clock generation circuit may be configured to generate the parallel clock signal by dividing a bit clock signal that is coupled to a clock input of the deserializer. The synchronization circuit may be configured to suppress output of the parallel clock signal when the data communication link is idle for a predefined first period of time and reestablish output of the parallel clock signal after a predefined second period of time that follows detection of a pulse on the data communication link. The clock generation circuit may be reset when the pulse is detected on the data communication link.

In various aspects of the disclosure, an apparatus includes means for decoding multibit data words in a serial datastream received from a data communication link in accordance with timing provided by a bit clock signal and means for generating a parallel clock signal. The means for generating a parallel clock signal may be configured to suppress output of the parallel clock signal when the data communication link is idle for a predefined first period of time and reestablish output of the parallel clock signal after a predefined second period of time that follows detection of a pulse on the data communication link. The multibit data words may be decoded in accordance with timing provided by the parallel clock signal.

In various aspects of the disclosure, a method for synchronizing a communication interface circuit includes generating multibit data words by converting a serial datastream received from a data communication link in accordance with timing provided by a bit clock signal, dividing the bit clock signal to obtain a parallel clock signal, suppressing output of the parallel clock signal when the data communication link is idle for a predefined first period of time, reestablishing output of the parallel clock signal after a predefined second period of time that follows detection of a pulse on the data communication link, and outputting the multibit data words in accordance with timing provided by the parallel clock signal.

In certain aspects, the clock generation circuit includes a clock divider configured to count cycles of the bit clock signal. The cycles of the bit clock signal counted by the clock divider may correspond to a number of serial bits used to generate a single multibit data word. The first period of time may be defined in proportion to a first number of cycles of the parallel clock signal. The second period of time may be defined in proportion to a second number of cycles of the parallel clock signal. The second period of time may be greater than one cycle of the parallel clock signal.

In certain aspects, the pulse has a duration that is defined as a number of cycles of the bit clock signal. In some examples, the pulse is detected in a pattern of bits clocked through the deserializer.

### BRIEF DESCRIPTION OF THE DRAWINGS

FIG. 1 illustrates an example of a system-on-a-chip in accordance with certain aspects of the present disclosure.

FIG. 2 illustrates an apparatus employing interconnected chiplets.

FIG. 3 illustrates an example of an apparatus in which chiplets are stacked vertically on a substrate.

FIG. 4 illustrates an example of a data communication interface that may be adapted in accordance with certain aspects of the present disclosure.

FIG. 5 illustrates an example of synchronization loss in a serial communication interface.

FIG. 6 illustrates an example of an in-band synchronization signal that is configured in accordance with certain aspects of this disclosure.

FIG. 7 illustrates an example of a serial communication interface that implements in-band synchronization in accordance with certain aspects of the present disclosure.

FIG. 8 illustrates an example of a synchronization control circuit that may be configured in accordance with certain aspects of this disclosure.

FIG. 9 is a flowchart of a method for synchronizing a communication interface circuit in accordance with certain aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

Data communication links employed by system-on-a-chip (SoC) and other integrated circuit (IC) devices to connect processors with modems and other peripherals may be operated in accordance with industry or proprietary standards or protocols associated with certain functions or types of devices. According to certain aspects of the disclosure, a serial data link may be used to interconnect electronic devices that are subcomponents of an apparatus such as a cellular phone, a smart phone, a session initiation protocol (SIP) phone, a laptop, a notebook, a netbook, a smartbook, a personal digital assistant (PDA), a satellite radio, a global positioning system (GPS) device, a smart home device, intelligent lighting, a multimedia device, a video device, a digital audio player (e.g., MP3 player), a camera, a game console, an entertainment device, a vehicle component, a wearable computing device (e.g., a smart watch, a health or fitness tracker, eyewear, etc.), an appliance, a sensor, a security device, a vending machine, a smart meter, a drone, a multicopter, or any other similar functioning device.

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

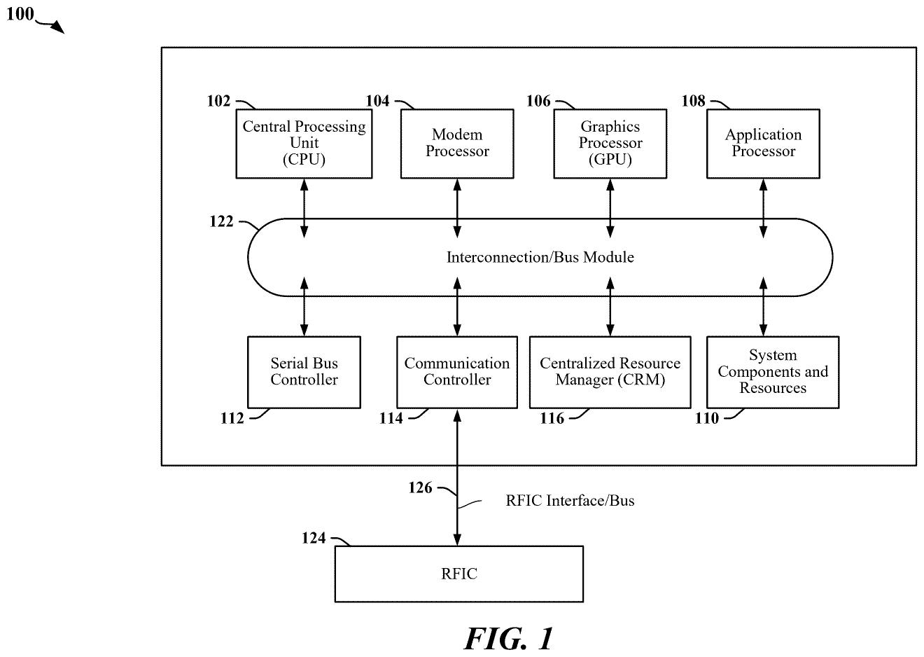

FIG. 1 illustrates an example of an apparatus 100 in which certain components and interconnections can be implemented in an SoC. The apparatus 100 may include a number of heterogeneous processors, such as a central processing unit (the CPU 102), a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., power/voltage rails), as well as for more coordinated cooperation between cores.

The apparatus 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The apparatus 100 may further include a serial bus controller 112 such as a Universal Serial Bus (USB) controller, a communication controller 114, and a centralized resource manager (CRM) 116. The apparatus 100 may also include an input/output module (not illustrated) for communicating with resources external to the SoC, each of which may be shared by two or more of the internal SoC components.

The processors 102, 104, 106, 108 may be interconnected to the serial bus controller 112, the communication controller 114, system components and resources 110, CRM 116, and/or other system components via an interconnection/bus module 122, which may include an array of reconfigurable logic gates and/or implement a bus architecture. Communications may also be provided by advanced interconnects, such as high-performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously. The communication controller 114 may be a specialized hardware module configured to manage and/or prioritize the flow of data to and from a radio frequency integrated circuit (RFIC) 124 via one or more RFIC communication links 126.

The communication controller 114 may include one or more processors configured to perform operations with the RFIC 124, often within time constraints specified or required by communication standards and protocols. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the RFIC 124 may be part of the apparatus 100.

The increasing complexity and functionality required from semiconductor devices tends to increase the physical dimensions of integrated circuit devices in which they are embodied. An upper limit on integrated circuit device is the maximum “reticle” size that in some instances refers to the size of the photomask used to manufacture the integrated circuit devices. Chiplets provide one approach to avoiding the maximum reticle size. Moreover, chiplet technology can be used to address some of the performance, power and size design requirements for complex SoCs, including SoCs used in certain mobile or wearable devices. The use of smaller dies can improve manufacturing yields.

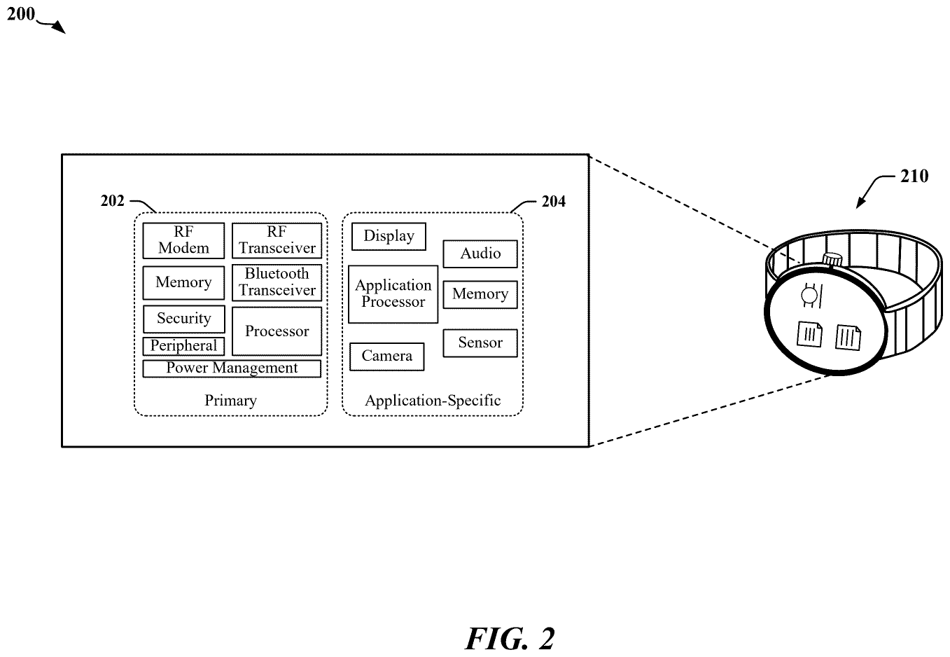

FIG. 2 illustrates an example of an apparatus 200 in which certain components are implemented using multiple chiplets that are interconnected using one or more data communication buses. In one example, the apparatus 200 may be enclosed within a portable or wearable processing and/or communication device (each of which being referred to herein as a portable communication device or PCD), sensors, instruments, appliances and other such devices include one or more ICs. These devices may include mobile phones, tablet computers, palmtop computers, portable digital assistants (PDAs), portable game consoles, and other portable electronic devices such as the illustrated smartwatch 210. PCDs commonly contain integrated circuits or SoCs that include numerous components or subsystems designed to work together to deliver functionality to a user. The various SoC subsystems may communicate with each other via one or more intra-chip data buses or similar data communication interconnects. PCDs may have multiple SoCs that communicate with each other via similar inter-chip interconnects. The ICs are typically packaged in an IC package, which may be referred to as a “semiconductor package” or “chip package.” The IC package typically includes a package substrate and one or more IC chips or other electronic modules mounted to the package substrate to provide electrical connectivity to the IC chips. For example, an IC chip in an IC package may be configured as an SoC. The IC chips are electrically coupled to other IC chips and/or to other components in the IC package through electrical coupling to metal lines in the package substrate. The IC chips can also be electrically coupled to other circuits outside the IC package through electrical connections of external metal interconnects (e.g., solder bumps) of the IC package.

Chiplet technology can be used to address some of the performance, power and size design requirements for complex SoCs used in certain mobile or wearable devices. The block diagram in FIG. 2 illustrates certain aspects of an apparatus 200 that can be constructed using chiplets. The apparatus 200 may be configured by selecting a combination of chiplets that implement certain subsystems or distinct functional elements. In the illustrated example, the apparatus 200 includes a set of primary chiplets 202 that enable the apparatus 200 to perform core processing, security and communication functions. The set of primary chiplets 202 include a processor, memory and one or more modems. The illustrated apparatus 200 also includes a set of application-specific chiplets 204 that includes an application processor, display driver, camera interface and audio controller. In a remote sensing device or appliance, the audio-visual components could be omitted and may be replaced with analog-to-digital controllers, for example.

The apparatus 200 may include a variety of processing engines, such as central processing units (CPUs) with multiple cores, graphical processing units (GPUs), digital signal processors (DSPs), neural processing units (NPUs), wireless transceiver units (also referred to as modems), peripherals, display and imaging interfaces, etc. Each of these subsystems and other functional elements can be implemented as an individual chiplet, or as a combination of chiplets. The chiplets included in the apparatus 200 can be proprietary or may be acquired from a variety of sources. An SoC may be constructed from chiplets manufactured at different process nodes and/or operated at different voltages.

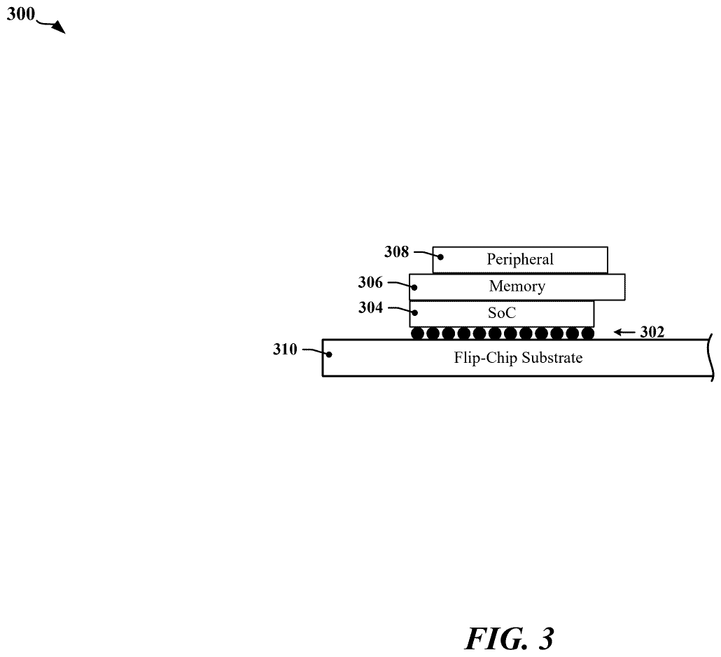

FIG. 3 illustrates an example of an SoC 300 in which certain chiplets 304, 306, 308 are stacked vertically on a substrate 310. Some chiplets can be included in stacks that are deployed across the surface of the substrate 310, while other chiplets may be individually mounted on the surface of the substrate. Chiplets may be mounted on the surface of the substrate using solder balls 302 that provide electrical and/or thermal coupling between substrate and the mounted chiplets. An interconnect structure may be formed that enables chiplets 304, 306, 308 in a stack of chiplets to communicate with one another, with other chiplets mounted on the substrate 310 and with input/output structures that connect the apparatus 200 with other circuits, displays, imaging sensors and other peripherals with an apparatus.

The use of chiplets can reduce the areal size of the substrate 310 and increase three-dimensional packing density. The constituent chiplets may provide complex features and high performance within a smaller form-factor operated at lower power specifications. Moreover, each chiplet may define multiple power domains, operate at different frequencies and different chiplets may manage power/frequency modes independently and. In some instances, two or more chiplets may be operated in mutually exclusive power states. Additionally, operating conditions for an SoC depend on the type, number and arrangement of chiplets included on the substrate in addition to the modes of operation defined by applications. It is necessary to consider power usage by all chiplets in the SoC in order to ensure compliance with power budgets assigned for an application or device.

Conventional chiplet-based implementations suffer from limitations that include complex or difficult interconnect routing, local hotspots arising from routing congestion caused by connection architecture and challenges to signal timing specifications. In certain examples, local hotspots can arise from routing congestion, increased feature complexity and circuit concentrations. In certain examples, signal timing specifications can be compromised due to the necessity for an increased number of isolation clamps due to logic placement, number of voltage domains and reduced floorplan. Long wire crossings between chiplets can cause routing congestion.

Each chiplet in an SoC may be included to perform a specific function or type of function and the configuration of the chiplets can introduce further complexities and challenges for designers. For example, one chiplet may include radio frequency front end circuits that produce high frequency signals ranging up to 5 GHz or more, and may further include interfaces that are used by low-frequency power management circuits. A designer may import previously defined circuit blocks to implement some of the internal functions. These circuit blocks may be referred to as macros. Imported circuit blocks for a given process technology may be described, characterized or defined by a set of masks, hardware description language, specifications and test data. Commercially available or proprietary circuit blocks may be referred to as hard macros. Hard macros are tested and verified for a set of design and operating specifications. It is common for hard macros and other circuit blocks to define multiple power domains.

The use of chiplets can significantly increase bandwidth demands to support communications between circuits located on different chiplets. Increased bandwidth may be obtained by increasing the number of communication links within between chiplets, thereby increasing complexity of routing. The allocation of input/output (I/O) pins or terminals may require tradeoffs that result in the reduction of I/O pins available for communicating control signals used to ensure synchronization between transmitters and receivers. In certain circumstances, loss of synchronization can substantially limit maximum data throughput rates, may prevent a data communication link from adhering to latency specifications and may render the data communication link unusable for applications associated with time-critical constraints. Certain aspects of this disclosure relate to the provision of in-band control signaling that can be used for synchronization with minimal degradation in latency performance. For the purposes of this disclosure, in-band signaling refers to the embedding of control information within a bitstream transmitted over a serial communication link. The control information may be encoded in one or more bits that are provided inline, or between payload data.

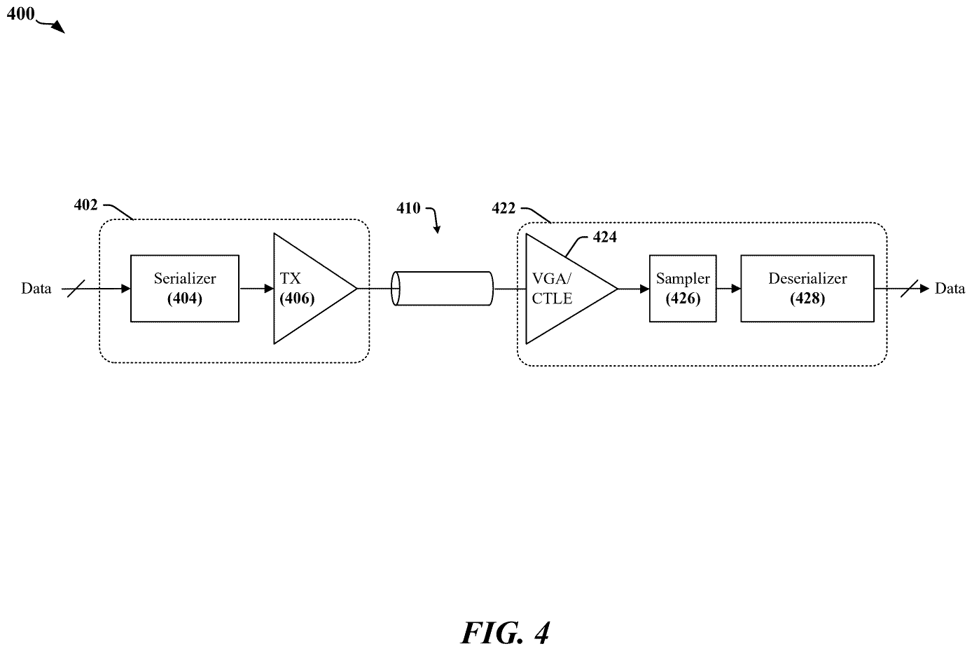

FIG. 4 illustrates an example of a data communication system 400 that may be adapted in accordance with certain aspects of the present disclosure. The data communication system 400 includes a transmitter 402, a data communication channel 410, and a receiver 422. The transmitter 402 may be provided in a first device that is configured to transmit a data signal to a second device. The data communication channel 410 provides a transmission medium through which the data signal propagates from the first device to the second device. The receiver 422 may be provided in the second device and may be configured to receive and process the data signal.

In one example, the transmitter 402 includes a serializer 404 configured to convert parallel data into serial data. The transmitter 402 further includes a transmit driver 406 configured to encode the serial data in the data signal for transmission to the receiver 422 through the data communication channel 410.

The data communication channel 410 may be implemented using any type of transmission medium by which a data signal can propagate from the transmitter 402 to the receiver 422. Examples of the data communication channel 410 include one or more wires including twisted pairs of wires, metallization traces (which may include one or more vias) on a printed circuit board (PCB), stripline, microstrip, and/or coaxial cable.

In the illustrated example, the receiver 422 includes a VGA with a continuous time linear equalizer (CTLE), a sampler circuit 426 and a deserializer 428. The combined VGA and CTLE circuit may be referenced herein as the VGA/CTLE 424. Continuous time linear equalization may be configured to boost higher frequency components of a received data signal in order to bring all frequency components of the received data signal to a similar amplitude ratio before channel attenuation, improving jitter performance. The VGA/CTLE 424 may be configured to perform equalization and amplification of the received data signal. The sampler circuit 426 is configured to recover data from the received data signal using timing information provided by a clock signal associated with the received data signal. The deserializer 428 is configured to convert the recovered data into parallel data.

In high-speed applications, data throughput of a serial data link may be limited by a combination of factors that can include switching speed of circuits in the transmitter or receiver and the characteristics of the channel used to carry data signals, for example. Impedance mismatches, parasitic electromagnetic coupling and other factors can cause signal distortion. In various examples, one or more of the channels may be implemented using one or more metallization traces (which may include one or more vias) on a printed circuit board (PCB), stripline, microstrip, coaxial cable, twisted pairs of wires, etc. In many implementations, equalization circuits and capabilities are included in I/O circuits to compensate for signal distortions attributable to inter-symbol interference (ISI) and other effects that can combine to limit bandwidth in a channel. ISI can result when a first-received symbol interferes with subsequently received symbols due to reflections, frequency-dependent delays and other imperfections in the channel. A symbol may refer to signaling state within a unit interval (UI), or symbol interval, in which data is modulated or encoded in the waveform of a transmitted signal. In one example, a data bit may be transmitted over a channel or path of a communication link in one bit transmission interval. The terms “bit transmission interval” and “UI” may be used interchangeably in reference to certain data communication links.

Certain aspects of the disclosure are applicable to data communication interfaces that include serializer/deserializer (SERDES) circuits. An SoC may employ one or more high-speed data communication buses for interconnecting devices and subcircuits with the SoC or within the SoC. The high-speed data communication buses may be operated in accordance with standardized or proprietary bus protocols. An SoC implemented using multiple chiplets mounted on a common chip carrier may be coupled through high-speed data communication buses operated according to one or more proprietary or standards-defined protocols. A protocol may be selected for use based on application or requirements. High-speed comm SERDES-based data communication interfaces may be operated in accordance with Peripheral Component Interconnect Express (PCIe) or USB protocols, in accordance with Advanced High-Performance Bus (AHB) protocols defined by Advanced Microcontroller Bus Architecture (AMBA) specifications, and/or in accordance with protocols defined by Universal Chiplet Interconnect Express (UCIe) standards. Other bus architectures or protocols may be employed to satisfy design or application requirements. Certain bus architectures may be deployed to support inter-processor communications, inter-device communications, sensor support, high-speed communication and/or memory interfaces.

The ever-increasing complexity of semiconductor devices is typically accompanied by increasing demand for data communication bandwidth between SOCs and between chiplets within SoCs. Bandwidth demands can be met to some extent by increased data transmission frequencies, which are limited by circuit switching speeds, power consumption budgets and susceptibility to reliability issues that may be attributable to variations in manufacturing process, voltage and/or temperature (PVT), susceptibility of high-speed links to electromagnetic interference and so on. In many instances, bandwidth demands necessitate the use of an expanded number of data communication links, which requires increased numbers of input/output (I/O) terminals. In many implementations, I/O terminals are not available to communicate control signals that would be otherwise be usable for synchronization between transmitters and receivers. In certain circumstances, loss of synchronization can substantially limit expected data throughput rates, ability of a data communication link to meet latency specifications and the usability of a data communication link for applications associated with time-critical constraints.

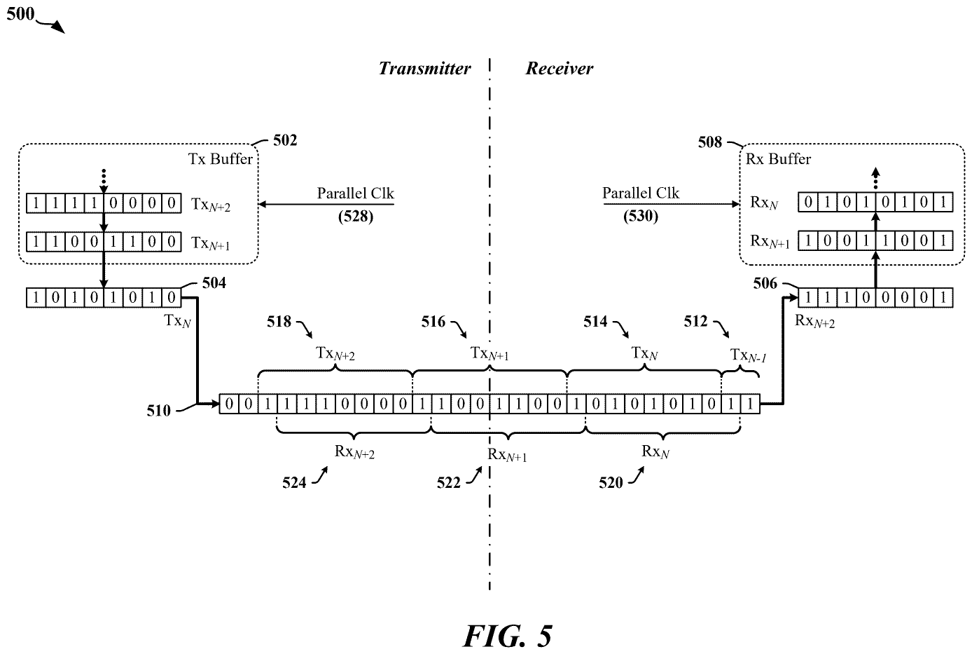

FIG. 5 illustrates an example of synchronization loss in a serial communication interface 500. On the transmitter side of the serial communication interface 500, parallel data propagates through a transmit buffer 502 in accordance with a transmit parallel data clock signal 528. In the illustrated example, the data is provided in 8-bit bytes although it can be anticipated that other-sized data elements may be supported by the transmit buffer 502 including, for example, data payloads provided in 16-bit elements, 24-bit elements, 32-bit elements, 64-bit elements, 128-bit elements, etc. In some implementations, different sizes of data elements may be used or defined to include parity or error correction bits in addition to the data payload.

In the illustrated example, data propagated through the transmit buffer 502 is provided to a serializer 504 that provides a serial datastream 510 for transmission over a communication link. On the receiver side of the serial communication interface 500, a deserializer 506 is configured to assemble parallel data from consecutive bits captured from the communication link. The parallel data assembled by the deserializer 506 is propagated through a receive buffer 508 in accordance with a receive parallel data clock signal 530. In some implementations, an output of the receive buffer 508 may be accessed by protocol handlers, processing circuits, memory interfaces, or other circuits in the receiver.

Loss of synchronization can occur when the parallel data clock signals 528 and 530 fall out of phase with one another. The transmit parallel data clock signal 528 defines the boundary between serialized data words transmitted in the serial datastream 510. In the illustrated example, the receive parallel data clock signal 530 is one bit transmission interval out of step with the transmit parallel data clock signal 528 and each data byte of parallel data captured by the receive buffer 508 includes one bit of data from the immediately preceding data byte. In the illustrated example, received parallel data byte 520 includes seven bits of the transmitted parallel data byte 514 combined with one bit of the immediately preceding transmitted parallel data byte 512, received parallel data byte 522 includes seven bits of the transmitted parallel data byte 516 combined with one bit of the immediately preceding transmitted parallel data byte 514, and received parallel data byte 524 includes seven bits of the transmitted parallel data byte 518 combined with one bit of the immediately preceding transmitted parallel data byte 516. The loss of boundary definition can render the misaligned, received parallel data meaningless and protocol handlers or other processing circuits may be required to perform parity checking and/or error checking on received data.

In some systems, synchronization is ensured when a “data valid” control signal is provided by the transmitter to mark the beginning of each word in each lane of a parallel data communication link. The addition of a synchronization control signal can consume additional power and contribute to link inefficiency. In some systems, the transmitter may be configured to encode payload data with error correction codes in order to permit the receiver to detect errors and, in some instances, correct errors in received data using information provided in the error correction codes. An example of data encoding is the 8b/10b coding scheme that maps 8-bit words to 10-bit symbols, thereby providing redundancy that can be used to convey error correction information. These types of coding scheme can increase processing requirements, power consumption and can reduce communication link efficiency. In some systems, boundaries between data elements can be marked by special symbols inserted between words. A receiver may buffer two parallel data words and search for the special marking symbol. This type of marking can introduce inefficiency due to startup latency and the requirement to use additional bit transmission intervals to transmit the special marking symbols.

A data communication interface configured in accordance with certain aspects of this disclosure can ensure synchronization between transmitter and receiver through the use of an in-band synchronization signal that is transmitted over a serial data communication link during transitions from an idle operating mode to active operating mode. An in-band synchronization signal may be provided by transmitting a pattern of bits over the serial link. The pattern of bits may be inserted inline with bits of payload data and/or between serialized data words. During transmission, the pattern of bits may be represented as one or more pulses that can be detected on a channel of the serial link. A receiver that detects the pattern of bits may be configured to reset timing circuits such that receiver clock signals are synchronized with transmitter clock signals. In one example, the receiver that detects the pattern of bits may be configured to reset one or more clock dividers in order that clock signals that control the operation of serializers and buffers for deserialized data are synchronized to the exact boundaries of transmitted data words. In another example, a deserializer, receive buffers and/or associated clock signals in a receiver may be reset concurrently with a serializer, transmit buffers and/or associated clock signals in the transmitter.

In some implementations, the data pattern has a predefined or specified duration and its transmission may commence or terminate at predefined or specified point in time before payload data is transmitted. The presently disclosed in-band synchronization signal can be transmitted without introducing latency to the data path when the communication link is in an active operating mode in which a serialized datastream is being transmitted. The presently disclosed in-band synchronization signal can be detected at the receiver without additional buffering.

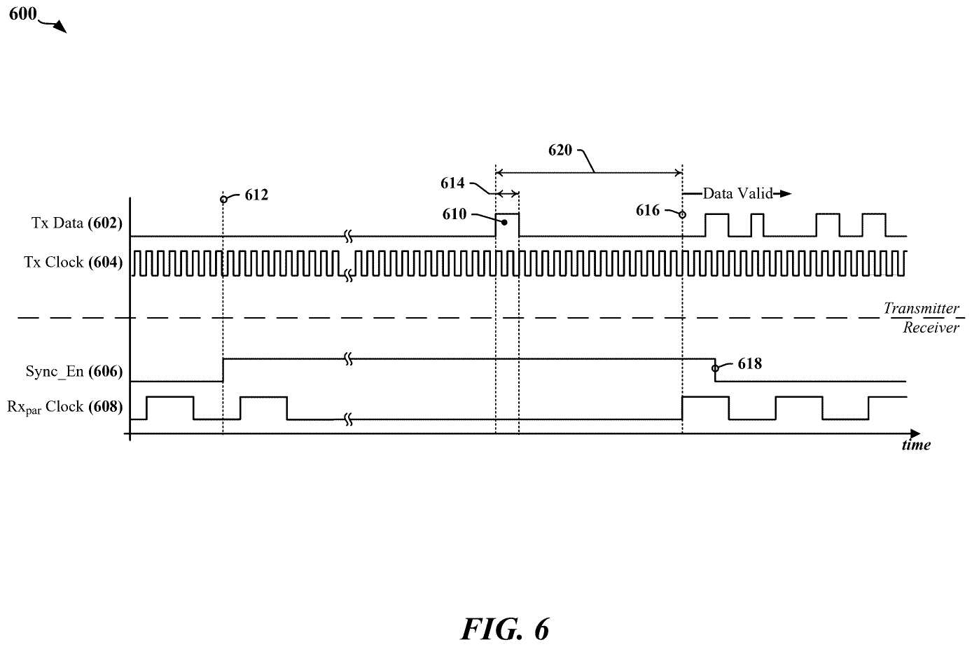

FIG. 6 is a timing diagram 600 that illustrates an example of an in-band synchronization signal that is configured in accordance with certain aspects of this disclosure. In this example, a transmitter is configured to encode a bitstream in a data signal 602 transmitted over a data line of a communication link in accordance with a transmitter serial clock signal 604. The period of the transmitter clock signal 604 may define or correspond to the duration of a bit transmission interval in which a bit of data is transmitted over the data line. In some implementations, the transmitter serial clock signal 604 may be transmitted over the data communication link. The transmitter may be further configured to transmit an in-band synchronization signal after the data signal 602 has been idle for some defined or specified duration of time. The data signal 602 is idle when no data is being transmitted. In the illustrated example, the data signal 602 is maintained in a low voltage signaling state when idle. In other examples, the data signal 602 is maintained in a high voltage signaling state when idle. In some implementations, the data line may be undriven when the data signal 602 is idle and the data line may be driven to the low voltage signaling state or the high voltage signaling state before the in-band synchronization signal is transmitted.

The transmitter may be configured to transmit the in-band synchronization signal after the data signal 602 has been idle for some number of cycles of the transmitter parallel data clock signal or the transmitter serial clock signal 604, and prior to transmitting valid payload data. For example, the in-band synchronization signal may be transmitted when the data signal 602 has been idle for 4 cycles of the transmitter parallel data clock signal or 32 cycles of the transmitter serial clock signal 604. The in-band synchronization signal comprises a pulse 610 in the data signal 602 that may have a pulse duration 614 that corresponds to a predefined number of bit transmission intervals. In the illustrated example, the pulse duration 614 corresponds to two bit transmission intervals. In one example, the pulse 610 may be provided by transmitting a data word with two bits set to binary ‘1’ and all other bits set to ‘0’.

The transmitter may be configured to transmit payload data at a point in time 616 after a synchronization interval 620. The synchronization interval 620 may be timed from the start of the pulse 610 or from the end of the pulse 610. The synchronization interval 620 may be timed from the start or end of a data word in which the pulse is encoded. In one example, the synchronization interval 620 has a duration that corresponds to 2 cycles of the transmitter parallel data clock signal. In another example, the synchronization interval 620 has a duration that corresponds to 30 cycles of the transmitter parallel data clock signal, when the serialized parallel data includes 16-bit words.

The receiver may be configured to assert a signal (e.g., the Sync_En signal 606) at a point in time 612 after detecting that the data signal 602 has been idle for some number of cycles of the receiver parallel data clock signal (e.g., the Rxₚₐᵣ_Clock signal 608. The Sync_En signal 606 may be configured to suppress capture of data output by a deserializer. In the illustrated example, assertion of the Sync_En signal 606 causes the Rxₚₐᵣ_Clock signal 608 to be conditionally suppressed. For example, the Sync_En signal 606 may be provided to a synchronization circuit that provides a timed response to detection of the in-band synchronization signal. In the illustrated example, the Sync_En signal 606 is de-asserted at a point in time 618 that occurs after suppression of the Rxₚₐᵣ_Clock signal 608 has been terminated.

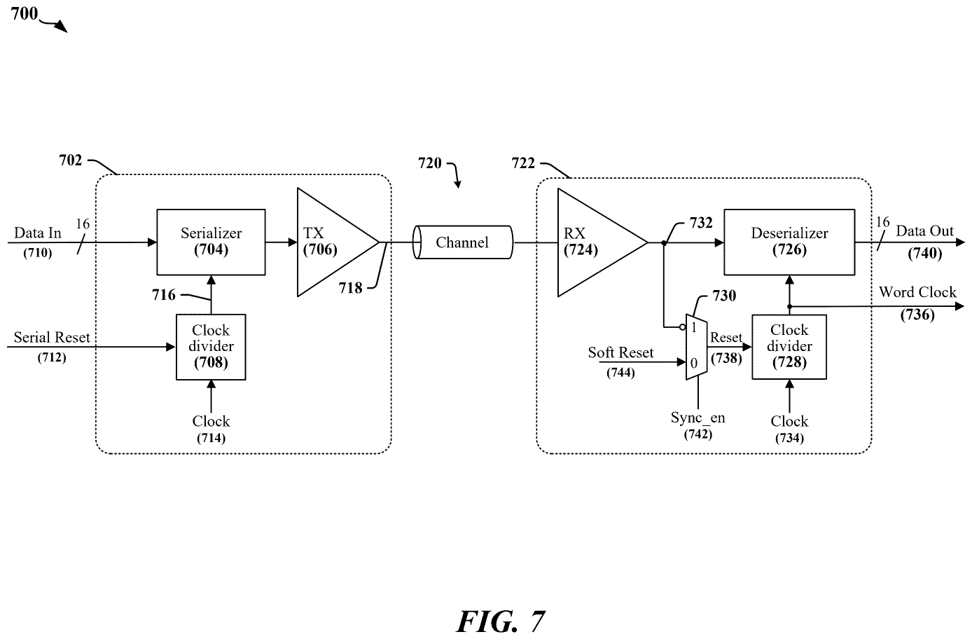

FIG. 7 illustrates an example of a serial communication interface 700 that may be configured to generate and respond to an in-band synchronization signal in accordance with certain aspects of the present disclosure. The serial communication interface 700 includes a transmitter 702, a data communication channel 720, and a receiver 722. The transmitter 702 may be provided in a first device that is configured to transmit a data signal 718 to a second device. The data communication channel 720 provides a transmission medium through which the data signal 718 propagates from the first device to the second device. The receiver 722 may be provided in the second device and may be configured to receive and process a propagated version of the data signal 718.

The illustrated transmitter 702 includes a serializer 704 configured to convert parallel data 710 into serial data, a clock divider 708 and a driver 706 configured to encode the serial data in the data signal 718 for transmission to the receiver 722 over the data communication channel 720. The clock divider 708 may be configured to receive a bit clock signal 714 and to provide a transmitter parallel data clock signal 716. In one example, the clock divider 708 may divide the bit clock signal 714 by the number of bits per parallel data word. The clock divider 708 may receive a reset signal 712 that can be used to restart or otherwise synchronize the transmitter parallel data clock signal 716. The transmitter 702 may be configured to initiate a synchronization procedure after an idle period by transmitting a pulse 610 in the data signal 718 in accordance with certain aspects of this disclosure.

The data communication channel 720 may be implemented using any type of transmission medium by which a data signal 718 can propagate from the transmitter 702 to the receiver 722. Examples of the data communication channel 720 include one or more wires including twisted pairs of wires, metallization traces (which may include one or more vias) on a printed circuit board (PCB), stripline, microstrip, and/or coaxial cable.

The receiver 722 includes a line receiver 724, a deserializer 726 and a clock divider 728. The clock divider 728 may be configured to receive a bit clock signal 734 and to provide a receiver parallel data clock signal 736. The clock divider 728 may divide the bit clock signal 734 by the number of bits per parallel data word. The clock divider 728 may be included in a clock generation circuit. In some implementations, the clock divider 728 may include a cascading tree of flipflops that is configured to divide the bit clock signal 734 by N², where N is a positive integer. In certain implementations, the clock divider 728 may include a binary counter that is configured to count cycles of the bit clock signal 734. The cycles of the bit clock signal 734 counted by the clock divider 728 may correspond to the number of serial bits used to generate a single parallel word, and may include payload bits, parity bits and/or the number of bits in an error correction code. For the purposes of this disclosure, the term “payload bits” may be used to refer to those data bits encoded in the data signal 718 that are generated by an application or protocol driver.

In some implementations, the clock divider 728 may be reset by a divider reset signal 738 that is asserted by an application using a software reset signal 744 or upon detection of a pulse in a received data signal 732 that is output by the line receiver 724 and that is representative of the data signal 718 during link synchronization events. In some implementations, the clock divider 728 may be reset upon detection of one or more bits clocked into the deserializer 726. In some implementations, the clock divider 728 may be reset upon detection of a pattern of bits clocked through the deserializer 726. For example, the pattern may be detected when a data word that has two bits set to binary ‘1’ and all other bits set to ‘0’.

In the illustrated example, the source of the divider reset signal 738 may be determined by a multiplexer 730 that is configured to select between the software reset signal 744 and the received data signal 732 based on signaling state of a synchronization enable signal (i.e., the Sync_En signal 742). The Sync_En signal 742 may correspond in certain respects to the Sync_En signal 606 depicted in FIG. 6. The deserializer 726 may be clocked by the bit clock signal 734 and may be configured to convert a serial datastream to a parallel data output 740.

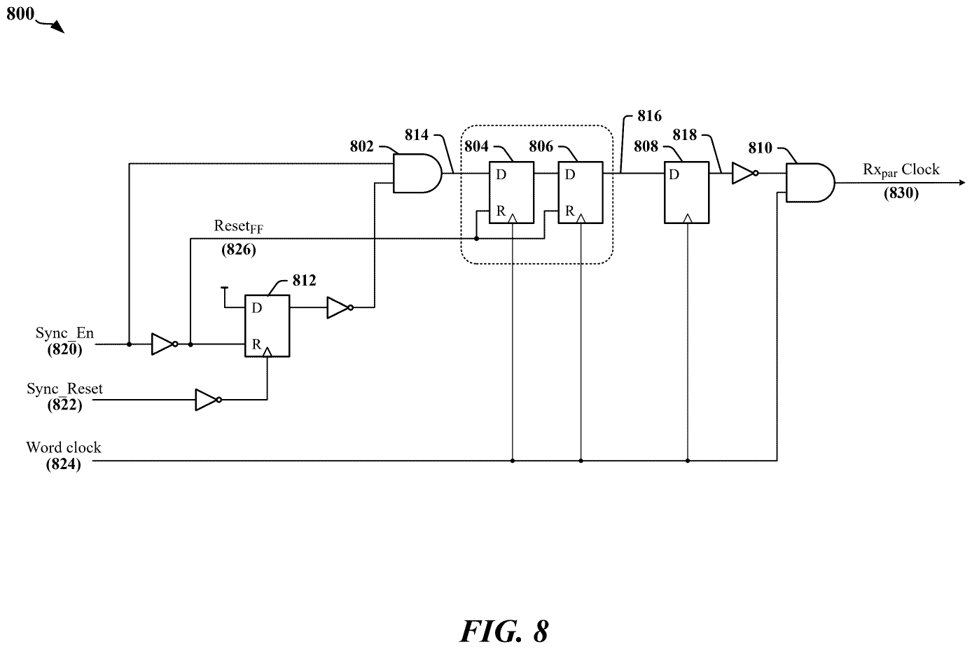

FIG. 8 illustrates an example of a synchronization control circuit 800 that may be configured in accordance with certain aspects of this disclosure. In the illustrated example, a flipflop reset signal 826 is coupled to the reset inputs of three flipflops 804, 806, 812. Flipflops 804 and 806 are clocked by a free-running parallel word clock signal 824. The flipflop reset signal 826 may be an inverted version of a synchronization enable signal (i.e., the Sync_En signal 820). In some implementations, additional flipflops may be coupled in series between flipflops 804, 806 and may respond to the flipflop reset signal 826 and be clocked by free-running parallel word clock signal 824. In some implementations, at least one of the flipflops 804, 806 may be omitted from the synchronization control circuit 800. Two of the flipflops 804, 806 are forced into a reset state when the Sync_En signal 820 is asserted and/or transitions to a high signaling state. The third flipflop 812 is forced into a reset state when the Sync_En signal 820 is deasserted and/or transitions to a low signaling state. Accordingly, the output of the third flipflop 812 is forced to the low signaling state when the Sync_En signal 820 is deasserted and synchronization is not being performed.

The data (D) input of the third flipflop 812 is coupled to a fixed voltage corresponding to the high signaling state, and the high signaling state is clocked through the third flipflop 812 as part of a synchronization procedure when an edge is provided in a synchronization reset signal (i.e., the Sync_Reset signal 822) that is coupled to the clock input of the third flipflop 812. In some implementations, the Sync_Reset signal 822 is derived from the divider reset signal 738 (see FIG. 7). An inverted version of the output of the third flipflop 812 is gated with the Sync_En signal 820 using an AND logic circuit 802 to obtain a parallel clock disable signal 814. The parallel clock disable signal 814 is in the low signaling state when Sync_En signal 820 is deasserted and synchronization is not being performed. The parallel clock disable signal 814 is driven to the low signaling state after the Sync_Reset signal 822 is asserted. The parallel clock disable signal 814 transitions from the low signaling state to the high signaling state when the Sync_En signal 820 is asserted and synchronization is being performed. The parallel clock disable signal 814 is in the high signaling state when Sync_En signal 820 is asserted and synchronization is being performed and before the Sync_Reset signal 822 is asserted.

The parallel clock disable signal 814 is propagated through flipflops 804, 806 when the Sync_En signal 820 is asserted and synchronization is being performed. Flipflop 808 is configured to receive the output 816 of flipflop 806 as an input. The outputs of flipflops 804, 806 are forced to a low signaling state when the Sync_En signal 820 is deasserted and in a low signaling state, and this low signaling state is subsequently propagated through flipflop 808. An inverted version of the output 818 of flipflop 808 gates the free-running parallel word clock signal 824 using an AND logic circuit 810. The output of the AND logic circuit 810 provides a receiver parallel clock signal (i.e., the Rxₚₐᵣ Clock 830) when synchronization is not being performed and before the Sync_Reset signal 822 is asserted. The Rxₚₐᵣ Clock 830 corresponds in some respects to the Rxₚₐᵣ Clock 608 illustrated in FIG. 6.

Flipflops 804, 806, 808 are clocked by a free-running parallel word clock signal 824. The free-running parallel word clock signal 824 may be obtained by dividing a bit transmission clock signal by the number of bits per parallel data word. In the illustrated example, flipflops 804, 806, 808 respond to rising edges in the free-running parallel word clock signal 824. Flipflop 808 ensures that a full cycle of Rxₚₐᵣ Clock 830 is completed after Sync_En signal 820 is asserted. In some implementations, the Sync_En signal 820 and Sync_Reset signal 822 may be controlled or generated by protocol handlers, processing circuits, or other circuits in a receiving device.

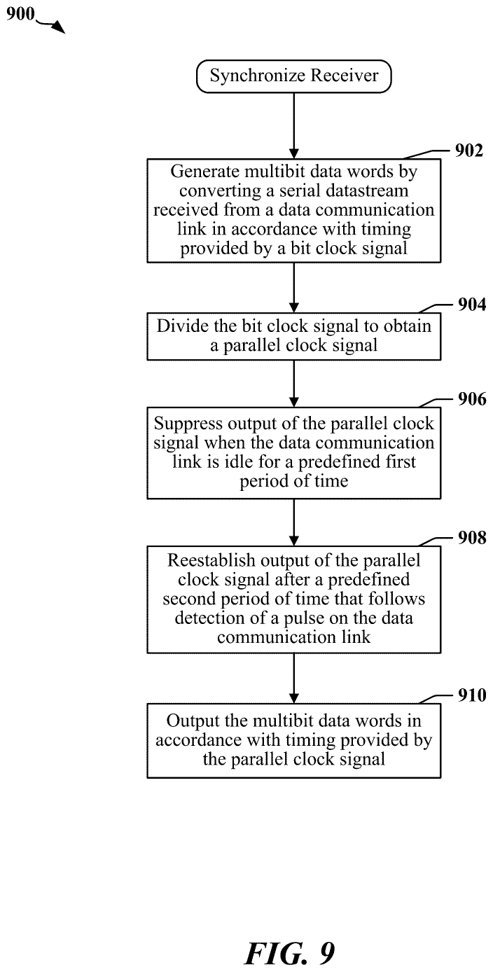

FIG. 9 is a flowchart 900 of a method for synchronizing a communication interface circuit in accordance with certain aspects of this disclosure. At block 902 in the illustrated method, multibit data words may be generated by converting a serial datastream received from a data communication link in accordance with timing provided by a bit clock signal. At block 904 in the illustrated method, the bit clock signal may be divided to obtain a parallel clock signal. At block 906 in the illustrated method, output of the parallel clock signal may be when the data communication link is idle for a predefined first period of time. At block 908 in the illustrated method, output of the parallel clock signal may be reestablished after a predefined second period of time that follows detection of a pulse on the data communication link. At block 910 in the illustrated method, the multibit data words may be output in accordance with timing provided by the parallel clock signal. In one example, outputting the multibit data words may include providing the data words to a buffer. In some instances, the buffer may be implemented as a first-in-first out buffer. In some instances, the buffer may be implemented as a parallel shift register.

In some implementations, the duration of each cycle of the parallel clock signal corresponds to a number of cycles of the bit clock signal used to capture a number of serial bits in a single multibit data word. In some implementations, the first period of time is defined as a first number of cycles of the parallel clock signal. The second period of time may be defined as a second number of cycles of the parallel clock signal. In some implementations, the pulse has a duration that is defined as a number of cycles of the bit clock signal. In some implementations, the pulse may be detected in a pattern of bits in the serial datastream.

The method illustrated in FIG. 9 may be performed in an IC device. In some implementations, the IC device comprises an SoC. The IC device may be one of multiple semiconductor dice mounted on a substrate. The IC device may be implemented as a chiplet, in some instances. The IC device may include means for decoding multibit data words in a serial datastream received from a data communication link in accordance with timing provided by a bit clock signal, means for generating a parallel clock signal configured to suppress output of the parallel clock signal when the data communication link is idle for a predefined first period of time and reestablish output of the parallel clock signal after a predefined second period of time that follows detection of a pulse on the data communication link. The multibit data words may be decoded in accordance with timing provided by the parallel clock signal.

In one example, the means for generating a parallel clock signal is implemented using a clock divider that is configured to count cycles of the bit clock signal. The clock divider may generate a parallel clock signal that has a period that corresponds to a number of cycles of the bit clock signal used to capture a number of serial bits in a single multibit data word. The first period of time may be defined as a first number of cycles of the parallel clock signal. The second period of time may be defined as a second number of cycles of the parallel clock signal. The means for decoding multibit data words may be implemented using a deserializer clocked by the bit clock signal. In some implementations, the pulse is detected in a pattern of bits in the serial datastream. In some implementations, the pulse has a duration that is defined as a number of cycles of the bit clock signal.

The method illustrated in FIG. 9 may be performed in a communication interface circuit that has a deserializer, a clock generation circuit and a synchronization circuit. The deserializer may be configured to convert a serial datastream received from a data communication link to multibit data words and to output the multibit data words in accordance with timing provided by a parallel clock signal. The clock generation circuit may be configured to generate the parallel clock signal by dividing a bit clock signal that is coupled to a clock input of the deserializer. The synchronization circuit may be configured to suppress output of the parallel clock signal when the data communication link is idle for a predefined first period of time and reestablish output of the parallel clock signal after a predefined second period of time that follows detection of a pulse on the data communication link. The clock generation circuit may be reset when the pulse is detected on the data communication link.

In certain implementations, the clock generation circuit includes a clock divider configured to count cycles of the bit clock signal. The cycles of the bit clock signal counted by the clock divider may correspond to a number of serial bits used to generate a single multibit data word. The first period of time may be defined in proportion to a first number of cycles of the parallel clock signal. The second period of time may be defined in proportion to a second number of cycles of the parallel clock signal. The second period of time may be greater than one cycle of the parallel clock signal.

In certain implementations, the pulse has a duration that is defined as a number of cycles of the bit clock signal. In some examples, the pulse is detected in a pattern of bits clocked through the deserializer.

Some implementation examples are described in the following numbered clauses:
1. A communication interface circuit, comprising: a deserializer configured to convert a serial datastream received from a data communication link to multibit data words and to output the multibit data words in accordance with timing provided by a parallel clock signal; a clock generation circuit configured to generate the parallel clock signal by dividing a bit clock signal that is coupled to a clock input of the deserializer; and a synchronization circuit configured to: suppress output of the parallel clock signal when the data communication link is idle for a predefined first period of time; and re-establish output of the parallel clock signal after a predefined second period of time that follows detection of a pulse on the data communication link, wherein the clock generation circuit is reset when the pulse is detected on the data communication link.
2. The clock generation circuit as described in clause 1, wherein the clock generation circuit comprises a clock divider configured to count cycles of the bit clock signal.
3. The clock generation circuit as described in clause 2, wherein a number of the cycles of the bit clock signal counted by the clock divider corresponds to a number of serial bits used to generate a single multibit data word.
4. The clock generation circuit as described in clause 1 or clause 2, wherein the first period of time is defined as a number of cycles of the parallel clock signal.
5. The clock generation circuit as described in any of clauses 1-4, wherein the second period of time is defined as a number of cycles of the parallel clock signal.
6. The clock generation circuit as described in any of clauses 1-5, wherein the second period of time is greater than one cycle of the parallel clock signal.
7. The clock generation circuit as described in any of clauses 1-6, wherein the pulse has a duration that is defined as a number of cycles of the bit clock signal.
8. The clock generation circuit as described in any of clauses 1-7, wherein the pulse is detected in a pattern of bits clocked through the deserializer.
9. An apparatus, comprising: means for decoding multibit data words in a serial datastream received from a data communication link in accordance with timing provided by a bit clock signal; means for generating a parallel clock signal configured to: suppress output of the parallel clock signal when the data communication link is idle for a predefined first period of time; and reestablish output of the parallel clock signal after a predefined second period of time that follows detection of a pulse on the data communication link, wherein the multibit data words are decoded in accordance with timing provided by the parallel clock signal.
10. The apparatus as described in clause 9, wherein the means for generating a parallel clock signal comprises a clock divider configured to count cycles of the bit clock signal that has a period that corresponds to a number of cycles of the bit clock signal used to capture a number of serial bits in a single multibit data word.
11. The apparatus as described in clause 9 or clause 10, wherein the first period of time is defined as a first number of cycles of the parallel clock signal.
12. The apparatus as described in any of clauses 9-11, wherein the second period of time is defined as a second number of cycles of the parallel clock signal.
13. The apparatus as described in any of clauses 9-12, means for decoding multibit data words comprises a deserializer clocked by the bit clock signal.
14. The apparatus as described in any of clauses 9-13, wherein the pulse is detected in a pattern of bits in the serial datastream.
15. The apparatus as described in any of clauses 9-14, wherein the pulse has a duration that is defined as a number of cycles of the bit clock signal.
16. A method for synchronizing a communication interface circuit, comprising: generating multibit data words by converting a serial datastream received from a data communication link in accordance with timing provided by a bit clock signal; dividing the bit clock signal to obtain a parallel clock signal; suppressing output of the parallel clock signal when the data communication link is idle for a predefined first period of time; reestablishing output of the parallel clock signal after a predefined second period of time that follows detection of a pulse on the data communication link; and outputting the multibit data words in accordance with timing provided by the parallel clock signal.
17. The method as described in clause 16, wherein each cycle of the parallel clock signal has a duration that corresponds to a number of cycles of the bit clock signal used to capture a number of serial bits in a single multibit data word.
18. The method as described in clause 16 or clause 17, wherein the first period of time is defined as a first number of cycles of the parallel clock signal, and wherein the second period of time is defined as a second number of cycles of the parallel clock signal.
19. The method as described in any of clauses 16-18, wherein the pulse has a duration that is defined as a number of cycles of the bit clock signal.
20. The method as described in any of clauses 16-19, wherein the pulse is detected in a pattern of bits in the serial datastream.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A communication interface circuit, comprising:
a deserializer configured to convert a serial datastream received from a data communication link to multibit data words and to output the multibit data words in accordance with timing provided by a parallel clock signal;
a clock generation circuit configured to generate the parallel clock signal by dividing a bit clock signal that is coupled to a clock input of the deserializer; and
a synchronization circuit configured to:
suppress output of the parallel clock signal when the data communication link is idle for a predefined first period of time; and
re-establish output of the parallel clock signal after a predefined second period of time that follows detection of a pulse on the data communication link,
wherein the clock generation circuit is reset when the pulse is detected on the data communication link.

2. The clock generation circuit of claim 1, wherein the clock generation circuit comprises a clock divider configured to count cycles of the bit clock signal.

3. The clock generation circuit of claim 2, wherein a number of the cycles of the bit clock signal counted by the clock divider corresponds to a number of serial bits used to generate a single multibit data word.

4. The clock generation circuit of claim 1, wherein the first period of time is defined as a number of cycles of the parallel clock signal.

5. The clock generation circuit of claim 1, wherein the second period of time is defined as a number of cycles of the parallel clock signal.

6. The clock generation circuit of claim 1, wherein the second period of time is greater than one cycle of the parallel clock signal.

7. The clock generation circuit of claim 1, wherein the pulse has a duration that is defined as a number of cycles of the bit clock signal.

8. The clock generation circuit of claim 1, wherein the pulse is detected in a pattern of bits clocked through the deserializer.

9. An apparatus, comprising:
means for decoding multibit data words in a serial datastream received from a data communication link in accordance with timing provided by a bit clock signal; and
means for generating a parallel clock signal configured to:
suppress output of the parallel clock signal when the data communication link is idle for a predefined first period of time; and
reestablish output of the parallel clock signal after a predefined second period of time that follows detection of a pulse on the data communication link,
wherein the multibit data words are decoded in accordance with timing provided by the parallel clock signal.

10. The apparatus of claim 9, wherein the means for generating a parallel clock signal comprises a clock divider configured to count cycles of the bit clock signal that has a period that corresponds to a number of cycles of the bit clock signal used to capture a number of serial bits in a single multibit data word.

11. The apparatus of claim 9, wherein the first period of time is defined as a first number of cycles of the parallel clock signal.

12. The apparatus of claim 9, wherein the second period of time is defined as a second number of cycles of the parallel clock signal.

13. The apparatus of claim 9, means for decoding multibit data words comprises a deserializer clocked by the bit clock signal.

14. The apparatus of claim 9, wherein the pulse is detected in a pattern of bits in the serial datastream.

15. The apparatus of claim 9, wherein the pulse has a duration that is defined as a number of cycles of the bit clock signal.

16. A method for synchronizing a communication interface circuit, comprising:
generating multibit data words by converting a serial datastream received from a data communication link in accordance with timing provided by a bit clock signal;
dividing the bit clock signal to obtain a parallel clock signal;
suppressing output of the parallel clock signal when the data communication link is idle for a predefined first period of time;
reestablishing output of the parallel clock signal after a predefined second period of time that follows detection of a pulse on the data communication link; and
outputting the multibit data words in accordance with timing provided by the parallel clock signal.

17. The method of claim 16, wherein each cycle of the parallel clock signal has a duration that corresponds to a number of cycles of the bit clock signal used to capture a number of serial bits in a single multibit data word.

18. The method of claim 16, wherein the first period of time is defined as a first number of cycles of the parallel clock signal, and wherein the second period of time is defined as a second number of cycles of the parallel clock signal.

19. The method of claim 16, wherein the pulse has a duration that is defined as a number of cycles of the bit clock signal.

20. The method of claim 16, wherein the pulse is detected in a pattern of bits in the serial datastream.
